(19) United States
(12) Patent Application Publication
(10) Pub. No.: US 2008/0081460 A1
(43) Pub. Date: Apr. 3, 2008

(54) Method of manufaturing a semiconductor device

(75) Inventors: Chang-Yeon Yoo, Seoul (KR); Chung-Ki Min, Yongin-si (KR); Yung-Jun Kim, Suwon-si (KR); Joon-Sang Park, Seoul (KR); Dong-Keun Kim, Seoul (KR); Tae-Eun Kim, Suwon-si (KR)

Correspondence Address: MILLS & ONELLO LLP, ELEVEN BEACON STREET, SUITE 605, BOSTON, MA, 02108, US

(73) Assignee: Samsung Electronics Co., Ltd., Suwon-si (KR)

(21) Appl. No.: 11/903,610

(22) Filed: Sep. 24, 2007

(30) Foreign Application Priority Data
Sep. 28, 2006 (KR) 10-2006-0094507

(51) Int. Cl. H01L 21/4763

(52) U.S. Cl. 438/624; 257/E21.495

(57) ABSTRACT

In a method of manufacturing a semiconductor device, a preliminary insulating layer is formed on a substrate. A photoresist pattern is formed on the preliminary insulating layer. A central portion of the preliminary insulating layer is partially etched using the photoresist pattern as an etch mask to form a preliminary insulating layer pattern including a central portion and a peripheral portion on the substrate. The peripheral portion of the photoresist pattern is higher than that of the central portion of the preliminary insulating layer pattern. The preliminary insulating layer pattern is polished to form a planarized insulating layer on the substrate.

### CROSS-REFERENCE TO RELATED APPLICATION

This application claims priority under 35 USC §119 to Korean Patent Application No. 10-2006-0094507 filed on Sep. 28, 2006, the disclosure of which is incorporated herein by reference in their entirety.

### BACKGROUND OF THE INVENTION

1. Field of the Invention

Example embodiments of the present invention relate to a method of manufacturing a semiconductor device. More particularly, example embodiments of the present invention relate to a method of manufacturing a semiconductor device employing a chemical mechanical polishing process to polish an insulating layer.

2. Description of the Related Art

A circuit pattern may be formed on a semiconductor substrate by sequentially or repeatedly performing various processes such as a deposition process, a photolithography process, an ion implantation process, a polishing process, a cleaning process, a drying process, etc. The polishing process is known as an integral step for improving an integration degree as well as a structural and electrical reliability of a semiconductor device. A chemical mechanical polishing (CMP) process has been used to polish a wafer. When the CMP process is performed, a wafer is planarized by a chemical reaction between slurry and a layer on the wafer and by a mechanic friction force between a polishing pad and the layer.

To increase a high capacity and a high integration degree of the semiconductor device, a multi-layered wiring structure is formed on a peripheral portion of the semiconductor substrate. The multi-layered wiring structure includes a plurality of wires and an insulating interlayer electrically insulating the wires from each other. The wires are vertically stacked on the peripheral portion of the semiconductor substrate. However, the wires may be unintentionally exposed and then polished in a subsequent polishing process of planarizing the insulating interlayer. Thus, particles generated from the wires in the polishing process may contaminate a CMP apparatus to thereby cause malfunctions therein.

Further, the semiconductor substrate may include a first central portion and a first peripheral portion surrounding the first central portion. The insulating interlayer may include a second central portion formed over the first central portion and a second peripheral portion formed over the first peripheral portion. When the polishing process is performed on the insulating interlayer, a difference in height may be generated between the second central portion and the second peripheral portion. The difference in height may deteriorate an overall flatness of the insulating layer.

For example, the insulating interlayer is interposed between the wires vertically stacked over the first peripheral portion of the semiconductor substrate to electrically insulate the wires from each other. When the insulating interlayer is planarized in the CMP process, the insulating interlayer is polished by the CMP apparatus of which an upper unit applies a polishing pressure to the insulating interlayer. As the polishing pressure applied to the second peripheral portion of the insulating interlayer is greater than that applied to the second central portion of the insulating interlayer, the polished amount of the second peripheral portion may be larger than that of the second central portion. Particularly, when the insulating interlayer is planarized by the CMP apparatus including a polishing pad that includes resin, a relatively high polishing pressure may be applied to the second peripheral portion of the insulating interlayer because of an elastic force of the polishing pad. Thus, the polished amount of the second peripheral portion may be larger than that of the second central portion such that the wires may be exposed and then polished by the polishing process for polishing the insulating interlayer. As a result, in case that another wire is formed on the insulating interlayer, an electrical short between the wires may occur and thus the semiconductor device may electrically fail.

### SUMMARY OF THE INVENTION

In accordance with aspects of the present invention there is provided a method of manufacturing a semiconductor device capable of enhancing a flatness of an insulating interlayer having a peripheral portion in which wires are formed and capable of preventing the wires from being exposed.

In accordance with one aspect of the present invention, there is provided a method of manufacturing a semiconductor device. In the method, a preliminary insulating layer is formed on a substrate. A photoresist pattern is formed on the preliminary insulating layer. A central portion of the preliminary insulating layer is partially etched using the photoresist pattern as an etch mask to form a preliminary insulating layer pattern including a central portion and a peripheral portion on the substrate. The peripheral portion of the photoresist pattern is higher than the central portion of the preliminary insulating layer pattern. The preliminary insulating layer pattern is polished to form a planarized insulating layer on the substrate.

Wires having a multi-layered structure may be formed on the substrate before forming the preliminary insulating layer.

In accordance with another aspect of the present invention, there is provided a method of manufacturing a semiconductor device. In the method, a preliminary insulating layer is formed on a substrate. The preliminary insulating layer includes a central portion and a peripheral portion surrounding the central portion. A buffer layer pattern is formed on the peripheral portion of the preliminary insulating layer. The buffer layer pattern has a polish rate substantially lower than that of the preliminary insulating layer. Upper portions of the buffer layer pattern and the preliminary insulating layer are polished to form a planarized insulating layer on the substrate.

The preliminary insulating layer may be formed using oxide and the buffer layer pattern may be formed using polysilicon, silicon oxynitride, or silicon nitride.

To form the buffer layer pattern, a buffer layer may be formed on the preliminary insulating layer. A photoresist pattern may be formed on the buffer layer. The buffer layer may be partially etched by using the photoresist pattern as an etch mask.

The method may further comprise partially etching the central portion of the preliminary insulating layer using the photoresist pattern as an etch mask after partially etching the buffer layer.

In accordance with another aspect of the present invention, a method of manufacturing a semiconductor device is provided. In the method, a multi-layered wire structure having a plurality of wires is formed on a substrate. A preliminary insulating layer is formed on the substrate to cover the multi-layered wire structure. The preliminary insulating layer includes a central portion and a peripheral portion surrounding the central portion. A buffer layer pattern is formed on the peripheral portion of the preliminary insulating layer. The buffer layer pattern has a polish rate substantially lower than that of the preliminary insulating layer. The buffer layer pattern and the preliminary insulating layer are polished to form a planarized insulating layer on the substrate.

To form the buffer layer pattern, a buffer layer may be formed on the preliminary insulating layer. A photoresist pattern may be formed on the buffer layer. A portion of the buffer layer located on the peripheral portion of the preliminary insulating layer may be etched using the photoresist pattern as an etch mask.

The preliminary insulating layer may be partially etched using the photoresist pattern as an etch mask before polishing the buffer layer pattern and the preliminary insulating layer.

The preliminary insulating layer may be formed using an oxide and the buffer layer pattern is formed using polysilicon, silicon oxynitride, or silicon nitride.

According to aspects of the present invention, a preliminary insulating layer pattern having a central portion and a peripheral portion protruded with respect to the central portion is formed. The preliminary insulating layer pattern is then polished to form an insulating layer having a relatively planar surface. Thus, wires formed inside the peripheral portion of the preliminary insulating layer pattern may not be exposed and then polished by a polishing process performed to polish the preliminary insulating layer pattern.

### BRIEF DESCRIPTION OF THE DRAWINGS

The present invention will become readily apparent by reference to the following detailed description when considered in conjunction with the accompanying drawings, wherein:

FIGS. 1 to 4 are cross-sectional views illustrating an example embodiment of a method of manufacturing a semiconductor device in accordance with aspects of the present invention; and

FIGS. 5 to 8 are cross-sectional views illustrating another example embodiment of a method of manufacturing a semiconductor device in accordance with aspects of the present invention.

### DETAILED DESCRIPTION OF ILLUSTRATIVE EMBODIMENTS

Hereinafter, aspects of the present invention will be described by explaining illustrative embodiments in accordance therewith, with reference to the attached drawings. The present invention may, however, be embodied in many different forms and should not be construed as limited to the example embodiments set forth herein. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments in accordance with the present invention are described herein with reference to cross-sectional illustrations that are schematic illustrations of idealized embodiments (and intermediate structures). As such, variations from the shapes of the illustrations as a result, for example, of manufacturing techniques and/or tolerances, are to be expected. Thus, example embodiments the present invention, should not be construed as limited to the particular shapes of regions illustrated herein, but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

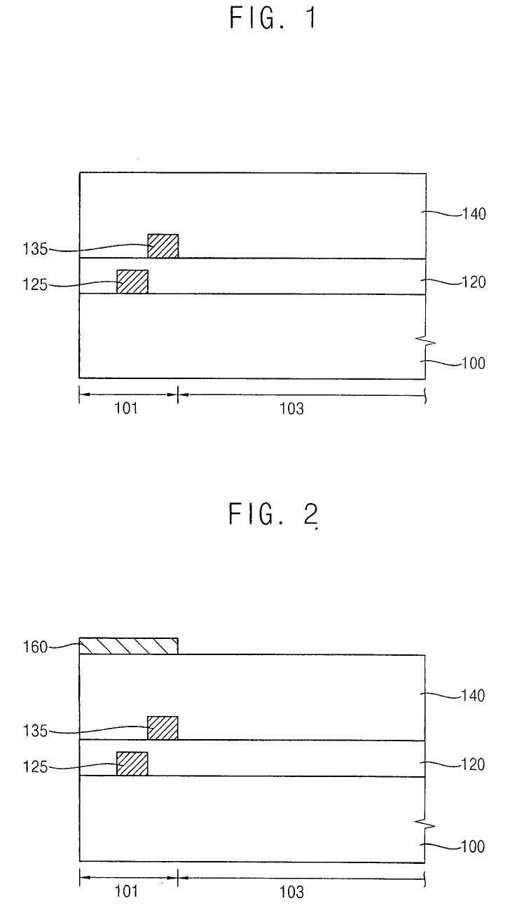

FIGS. 1 to 4 are cross-sectional views illustrating an example embodiment of a method of manufacturing a semiconductor device in accordance with an aspect of the present invention.

Referring to FIG. 1, a substrate 100 on which a first wire 125 is formed is provided. An insulating interlayer 120 is formed on the substrate 100 to cover the first wire 125. A second wire 135 is formed on the insulating interlayer 120. A preliminary insulating layer 140 is formed on the insulating interlayer 120 to cover the second wire 135.

The substrate 100 may be a semiconductor substrate, such as a silicon substrate, a silicon-on-insulator (SOI) substrate, a germanium substrate, a germanium-on-insulator (GOI) substrate, a silicon-germanium substrate, etc. In an example embodiment, the silicon substrate is used as the substrate 100.

The substrate 100 is divided into a central portion 103 and a peripheral portion 101 surrounding the central portion 103. Semiconductor chips (not shown) may be formed on the central portion 103 of the substrate 100. The semiconductor chip may include semiconductor elements such as a transistor, a capacitor, etc to form a multi-layered structure.

The first wire 125 is formed adjacent to the semiconductor chip. For example, the first wire 125 may be formed on the peripheral portion 101 of the substrate 100. The first wire 125 is electrically connected to the semiconductor chip to input an electric signal to the semiconductor chip.

The first wire 125 may be formed using a material having a relatively high electrical conductivity, such as metal or doped polysilicon. For example, the metal may be copper (Cu), aluminum (Al), silver (Ag), gold (Au), etc. These can be used alone or in a combination thereof. When the first wire 125 is formed using the metal, the first wire 125 may be formed on the substrate 100 by a sputtering process or a chemical vapor deposition (CVD) process.

The insulating interlayer 120 is formed on the substrate 100 to cover the first wire 125. The insulating interlayer 120 electrically isolates the first wire 125 from the second wire 135 that is to be formed by a subsequent process. The insulating interlayer 120 may be formed using an oxide or a nitride, as examples. In some example embodiments, the insulating interlayer 120 may be formed using the oxide.

When the insulating interlayer 120 is formed using the oxide, a process employed to form the insulating interlayer 120 may be a CVD process, a plasma-enhanced chemical vapor deposition (PE-CVD) process, an atomic layer deposition (ALD) process, a high-density plasma chemical vapor deposition (HDP-CVD) process, etc. Further, the insulating interlayer 120 may be formed using boron phosphorus silicate glass (BPSG), phosphorus silicate glass (PSG), undoped silicate glass (USG), spin-on-glass (SOG), flowable oxide (FOX), plasma enhanced tetraethylorthosilicate (PE-TEOS), high-density plasma chemical vapor deposition (HDP-CVD) oxide, etc.

Referring again to FIG. 1, the second wire 135 is formed on the insulating interlayer 120. The second wire 135 may be formed over the peripheral portion 101 of the substrate 100. The second wire 135 is electrically connected to the semiconductor chip (not shown) formed on the insulating interlayer 120 to input an electric signal to the semiconductor chip.

The second wire 135 may be formed using a material having a relatively high electrical conductivity, such as metal or doped polysilicon. For example, the metal may be copper (Cu), aluminum (Al), silver (Ag), gold (Au), etc. These can be used alone or in a combination thereof. When the second wire 135 is formed using the metal, the second wire 135 may be formed on the insulating interlayer 120 by a sputtering process or a CVD process.

Because the semiconductor chip has the multi-layered structure, the first and second wires 125 and 135 are formed on the substrate 100 such that the first and second wires 125 and 135 have multi-layered structures. In an example embodiment, the first and second wires 125 and 135 are vertically formed on the substrate 100 such that a double-layered wire structure including the first and second wires 125 and 135 is formed on the peripheral portion 101. In another example embodiment, at least three wires are vertically formed on the peripheral portion 101 such that a multi-layered wire structure including at least three wires is formed on the peripheral portion 101.

The preliminary insulating layer 140 is formed on the insulating interlayer 120 to cover the second wire 135. The preliminary insulating layer 140 may be formed using an oxide, a nitride, an oxynitride, etc. For example, the preliminary insulating layer 140 may be formed using silicon oxide. When the preliminary insulating layer 140 is formed using silicon oxide, a process employed to form the preliminary insulating layer 140 may be a CVD process, a PE-CVD process, an ALD process, an HDP-CVD process, etc. Further, the preliminary insulating layer 140 may be formed using boron phosphorus silicate glass (BPSG), phosphorus silicate glass (PSG), undoped silicate glass (USG), spin-on-glass (SOG), flowable oxide (FOX), plasma enhanced tetraethylorthosilicate (PE-TEOS), high-density plasma-chemical vapor deposition (HDP-CVD) oxide, etc.

Referring to FIG. 2, a photoresist pattern 160 is formed on the preliminary insulating layer 140 such that the photoresist pattern 160 vertically corresponds to the peripheral portion 101 after the preliminary insulating layer 140 is formed on the insulating interlayer 120.

Particularly, a photoresist film (not shown) is formed on the preliminary insulating layer 140. Thereafter, the photoresist film is selectively exposed to light. A development process is then performed on the exposed photoresist film so that the photoresist pattern 160 vertically corresponding to the peripheral portion 101 may be formed on the preliminary insulating layer 140.

The photoresist film may be a positive type photoresist film or a negative type photoresist film. When the negative type photoresist film is employed, a portion of the photoresist film formed over the peripheral portion 101 is exposed to light using a photo mask (not shown). A portion of the photoresist film located over the central portion 103 is then removed by the development process so that the photoresist film may be transformed into the photoresist film located over the peripheral portion 101. When the positive type photoresist film is employed, the portion of the photoresist film located over the central portion 103 is exposed to light using a photo mask. The exposed portion of the photoresist film is removed by the development process so that the photoresist film may be transformed into the photoresist pattern 160 located over the peripheral portion 103.

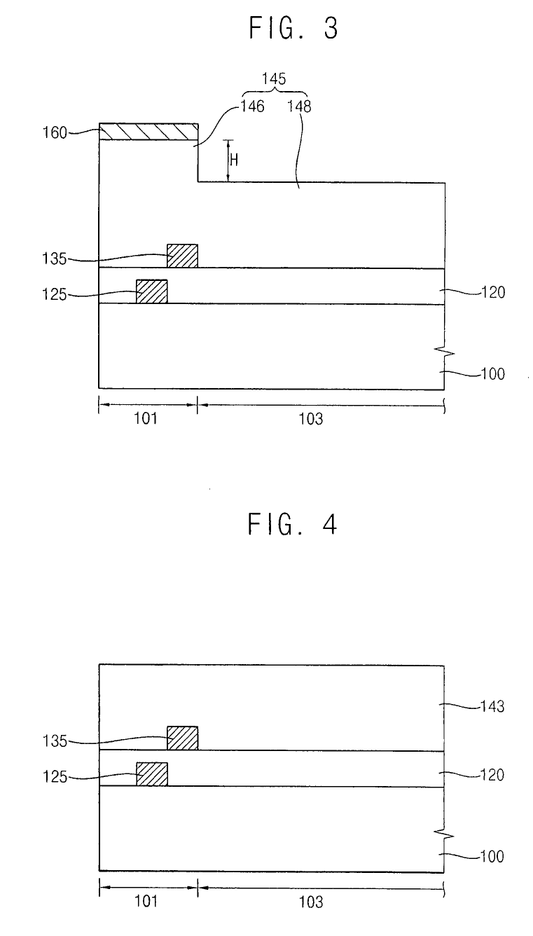

Referring to FIG. 3, the preliminary insulating layer 140 is partially etched using 15 the photoresist pattern 160 as an etch mask to form a preliminary insulating layer pattern 145 on the insulating interlayer 120. The preliminary insulating layer pattern 145 includes a central portion 148 and a peripheral portion 146. There is a difference in height between the central portion 148 and the peripheral portion 146. That is, the peripheral portion 146 has an upper face substantially higher than that of the central portion 148 by a distance H.

The distance H between the central portion 148 and the peripheral portion 146 may be adjusted in accordance with a condition of a polishing process such as a type of slurry, a rotation speed, etc, and a material included in the preliminary insulating layer pattern 145.

Referring to FIG. 4, the photoresist pattern 160 is removed from the preliminary insulating layer pattern 145 by an ashing and/or stripping process. The preliminary insulating layer pattern 145 is then polished to form a planarized insulating layer 143 on the insulating interlayer 120. The planarized insulating layer 143 may be formed by a polishing process such as a chemical mechanical polishing (CMP) process. When the planarized insulating layer 143 is formed by the CMP process, the peripheral portion 146 of the preliminary insulating layer pattern 145 may be polished at a rate substantially larger than the central portion 148 of the preliminary insulating layer pattern 145. That is, the polished amount of the peripheral portion 146 of the preliminary insulating layer pattern 145 may be larger than the central portion 148 of the preliminary insulating layer pattern 145. Thus, an entire upper face of the preliminary insulating layer pattern 145 is uniformly planarized to form the planarized insulating layer 143 having a uniformly planar upper face on the insulating interlayer 120.

When the first and second wires 125 and 135 are formed over the peripheral portion 101 of the substrate 100, the peripheral portion 146 where the first and second wires 125 and 135 are formed may be generally polished more than the central portion 148. However, the upper faces of the first and second wires 125 and 135 may not be exposed because the peripheral portion 146 has a thickness thicker than that of the central portion 148, in accordance with one embodiment. Thus, particles generated when the first and second wires 125 and 135 are polished may be reduced.

Thus, the first and second wires 125 and 135 may not be exposed when the preliminary insulating layer pattern 145 is polished to form the planarized insulating layer 143 on the insulating interlayer 120. In addition, a minimized thickness of the planarized insulating layer 143 covering the first and second wires 125 and 135 may be efficiently obtained. The planarized insulating layer 143 may have an improved transmittance because the planarized insulating layer 143 has the minimized thickness. Thus, in case that the semiconductor device is used as an image sensor, the planarized insulating layer 143 having the minimized thickness may improve an optical property of the image sensor.

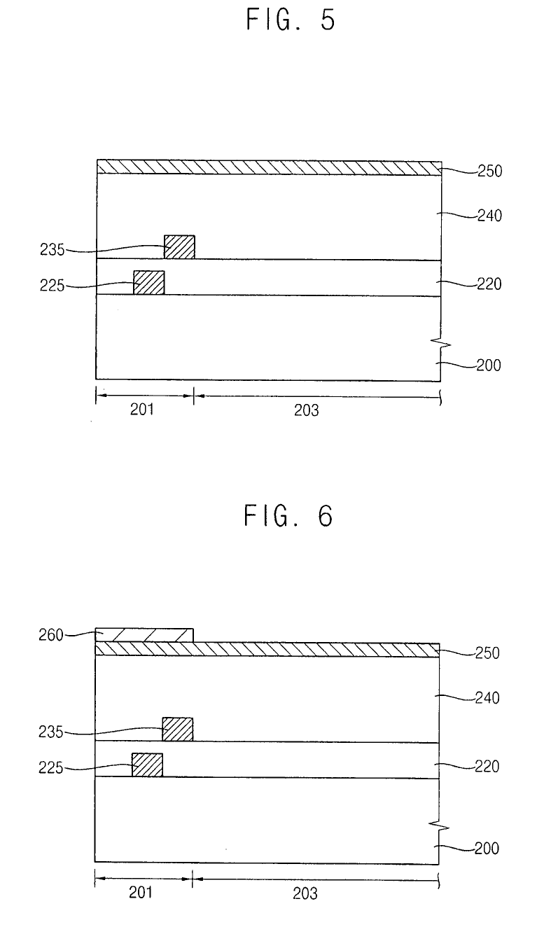

FIGS. 5 to 8 are cross-sectional views illustrating another example embodiment of a method of manufacturing a semiconductor device according to an aspect of the present invention.

Referring to FIG. 5, a first wire 225, an insulating interlayer 220, a second wire 235 and a preliminary insulating layer 240 are successively formed on a substrate 200. The substrate 200 may include a central portion 203 and a peripheral portion 201 surrounding the central portion 203. Processes for forming the first wire 225, the insulating interlayer 220, the second wire 235 and the preliminary insulating layer 240 are substantially the same as those for forming the first wire 125, the insulating interlayer 120, the second wire 135 and the preliminary insulating layer 140 previously illustrated with reference to FIGS. 1 to 4. Thus, any further description is omitted here.

A buffer layer 250 is formed on the preliminary insulating layer 240. The buffer layer 250 may be formed using a material having a polish rate substantially higher than that of the preliminary insulating layer 240. For example, when the preliminary insulating layer 240 is formed using an oxide, the buffer layer 250 may be formed using polysilicon, silicon oxynitride, or silicon nitride. The buffer layer 250 may be formed by a chemical vapor deposition (CVD) process or a physical vapor deposition (PVD) process.

Referring to FIG. 6, a photoresist film (not shown) is formed on the buffer layer 250. The photoresist film is then exposed to light using a photo mask (not shown). A development process is then performed on the photoresist film so that the photoresist film may be transformed into a photoresist pattern 260 located on the buffer layer 250.

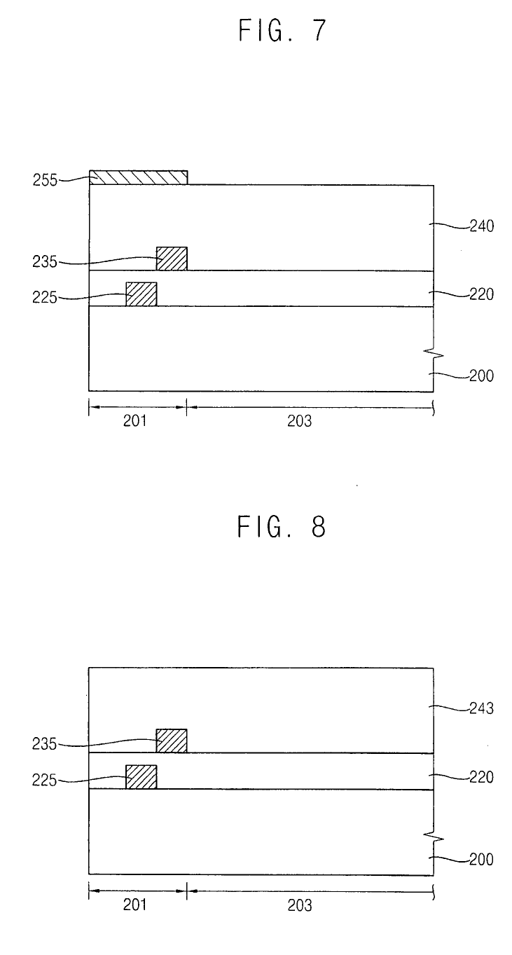

Referring to FIG. 7, the photoresist pattern 260 serves as an etch mask to form a buffer layer pattern 255. That is, the buffer layer 250 is partially etched using the photoresist pattern 260 as the etch mask to form the buffer layer pattern 255 on the preliminary insulating layer 240. The buffer layer pattern 255 is formed over the peripheral portion 201 of the substrate 200.

Because the buffer layer pattern 255 is formed using a material having a polish rate substantially lower than that of the preliminary, insulating layer 240, the buffer layer pattern 255 may protect a portion of the preliminary insulating layer 240 located under the buffer layer pattern 255 in a subsequent process for polishing the preliminary insulating layer 240.

Although not shown in the figures, a central portion of the preliminary insulating layer 240 may be further etched after the buffer layer pattern 255 is formed on the preliminary insulating layer 240. For example, the preliminary insulating layer 240 may be partially etched using the photoresist pattern 260 as an etch mask to form a preliminary insulating layer pattern (not shown) on the insulating interlayer 220. The preliminary insulating layer pattern may have the central portion having a thickness thinner than that of the peripheral portion, e.g., similar to the configuration shown in FIG. 3. That is, in such a case there is a difference in height between the central portion and the peripheral portion. Therefore, the difference in height and the buffer layer pattern 255 formed on the peripheral portion may prevent the peripheral portion of the preliminary insulating layer pattern from being excessively polished.

Referring to FIG. 8, the photoresist pattern is removed from the substrate 200 by an ashing and/or stripping process. The buffer layer pattern 225 and the preliminary insulating layer 240 are then polished to form a planarized insulating layer 243 on the insulating interlayer 220.

The planarized insulating layer 243 may be formed by a polishing process, such as a chemical mechanical polishing (CMP) process. The peripheral portion of the preliminary insulating layer 240 may have a polish rate substantially larger than the central portion of the preliminary insulating layer 240 in the CMP process. That is, the peripheral portion may have a polishing amount larger than that of the central portion. Because the buffer layer pattern 255 having a relatively low polish rate is formed on the peripheral portion of the preliminary insulating layer 240 prior to polishing the preliminary insulating layer 240, a surface of the preliminary insulating layer 240 is entirely planarized to form the planarized insulating layer 243 having a uniform upper face on the insulating interlayer 220.

When the first and second wires 225 and 235 are formed over the peripheral portion 201 of the substrate 200, the peripheral portion of the preliminary insulating layer 240 where the second wires 225 and 235 are formed may be polished more than the central portion of the preliminary insulating layer 240. However, because the buffer layer pattern 255 is formed on the peripheral portion of the preliminary insulating layer 240, the upper faces of the first and second wires 125 and 135 may not be exposed. Thus, particles generated when the first and second wires 125 and 135 are polished by excessively polishing the peripheral portion of the preliminary insulating layer 240, may be suppressed from being generated while polishing the preliminary insulating layer 240.

According to aspects of the present invention, a preliminary insulating layer has an upper face of a peripheral portion higher than that of a central portion. Thus, a surface of the preliminary insulating layer may be uniformly polished to form a planarized insulating layer having a uniform upper face on an insulating interlayer. Further, a buffer layer pattern having a relatively low polish rate may be formed on a peripheral portion of the preliminary insulating layer. Therefore, the surface of the preliminary insulating layer may be uniformly polished to form the planarized insulating layer on the insulating interlayer.

In addition, when wires are formed on the peripheral portion of the substrate, the peripheral portion may not be excessively polished, such that the wires may not be exposed. Thus, particles generated when the wires are polished by a polishing process required to planarizing the preliminary insulating layer may be reduced.

The foregoing is illustrative of aspects of the present invention and is not to be construed as limiting thereof. Although a few example embodiments have been described, those skilled in the art will readily appreciate that many modifications are possible in the example embodiments without materially departing from the novel teachings and advantages of this invention. Accordingly, all such modifications are intended to be included within the scope of the present invention as defined in the claims. Therefore, it is to be understood that the foregoing is illustrative of aspects of the present invention, which is not to be construed as limited to the specific embodiments disclosed, and that modifications to the disclosed embodiments, as well as other embodiments, are intended to be included within the scope of the appended claims. The present invention is defined by the following claims, with equivalents of the claims to be included therein.

What is claimed is:

1. A method of manufacturing a semiconductor device, the method comprising:
forming a preliminary insulating layer on a substrate;
forming a photoresist pattern on the preliminary insulating layer;
partially etching a central portion of the preliminary insulating layer using the photoresist pattern as an etch mask to form a preliminary insulating layer pattern including a central portion and a peripheral portion on the substrate, the peripheral portion of the photoresist pattern being higher than the central portion of the preliminary insulating layer pattern; and
polishing the preliminary insulating layer pattern to form a planarized insulating layer on the substrate.

2. The method of claim 1, further comprising forming wires having a multi-layered structure on the substrate before forming the preliminary insulating layer.

3. The method of claim 2, wherein forming the wires on the substrate comprises:
forming a first wire on the substrate;
forming an insulating interlayer on the substrate to cover the first wire; and
forming a second wire on the insulating interlayer.

4. A method of manufacturing a semiconductor device, the method comprising:
forming a preliminary insulating layer on a substrate, the preliminary insulating layer including a central portion and a peripheral portion surrounding the central portion;
forming a buffer layer pattern on the peripheral portion of the preliminary insulating layer, the buffer layer pattern having a polish rate substantially lower than that of the preliminary insulating layer; and
polishing upper portions of the buffer layer pattern and the preliminary insulating layer to form a planarized insulating layer on the substrate.

5. The method of claim 4, wherein the preliminary insulating layer is formed using oxide and the buffer layer pattern is formed using polysilicon, silicon oxynitride, or silicon nitride.

6. The method of claim 4, wherein forming the buffer layer pattern comprises:
forming a buffer layer on the preliminary insulating layer;
forming a photoresist pattern on the buffer layer; and
partially etching the buffer layer by using the photoresist pattern as an etch mask.

7. The method of claim 6, further comprising partially etching the central portion of the preliminary insulating layer using the photoresist pattern as an etch mask after partially etching the buffer layer.

8. A method of manufacturing a semiconductor device, the method comprising:
forming a multi-layered wire structure having a plurality of wires on a substrate;
forming a preliminary insulating layer on the substrate to cover the multi-layered wire structure, the preliminary insulating layer including a central portion and a peripheral portion surrounding the central portion;
forming a buffer layer pattern on the peripheral portion of the preliminary insulating layer, the buffer layer pattern having a polish rate substantially lower than that of the preliminary insulating layer; and
polishing the buffer layer pattern and the preliminary insulating layer to form a planarized insulating layer on the substrate.

9. The method of claim 8, wherein forming the buffer layer pattern comprises:
forming a buffer layer on the preliminary insulating layer;
forming a photoresist pattern on the buffer layer; and
etching a portion of the buffer layer located on the peripheral portion of the preliminary insulating layer using the photoresist pattern as an etch mask.

10. The method of claim 9, further comprising partially etching the preliminary insulating layer using the photoresist pattern as an etch mask before polishing the buffer layer pattern and the preliminary insulating layer.

11. The method of claim 8, wherein the preliminary insulating layer is formed using an oxide and the buffer layer pattern is formed using polysilicon, silicon oxynitride, or silicon nitride.
